(19) United States
(12) Patent Application Publication
(10) Pub. No.: US 2008/0298033 A1
(43) Pub. Date: Dec. 4, 2008

(54) POWER SUPPLY PLATFORM AND ELECTRONIC COMPONENT

(76) Inventors: Roy A. Smith, Naples, FL (US); Kenneth J. Smith, Naples, FL (US)

Correspondence Address: EDWARD M. LIVINGSTON, PA, 963 TRAIL TERRACE DRIVE, NAPLES, FL, 34103, US

(21) Appl. No.: 12/124,545

(22) Filed: May 21, 2008

Related U.S. Application Data
(60) Provisional application No. 60/932,827, filed on Jun. 1, 2007.

(51) Int. Cl. H01R 9/00; H05K 1/00

(52) U.S. Cl. 361/772; 361/748

(57) ABSTRACT

An electric power supply platform (1) made up of an upper conductive layer (2), a lower conductive layer (3), and a non-conductive insulating layer (4) sandwiched between the conductive layers (2), (3). Specially designed light emitting diodes (LEDs) (9) and a variety of other electronic components, each having one short lead (11) and one upper insulated long lead (10), may be removably attached to, displayed, and powered by the power platform (1) simply by inserting leads into the display surface (5) of the power platform (1). The leads of the LEDs (9) and other electronic components are different lengths so that the short lead (11) only comes into contact with the upper conductive layer (2) and the long lead (10) only comes into contact with the lower conductive layer (3) ensuring proper polarity. The leads (10), (11) of the LEDs (9) and/or other electronic components may be inserted into the display surface (5) at any location allowing the user to make any design he/she desires.

### CROSS REFERENCE TO RELATED APPLICATION

This application claims the benefit of U.S. Provisional Application No. 60/932,827 filed Jun. 1, 2007.

### BACKGROUND OF THE INVENTION

This invention relates to a power supply platform and electronic component for use in electronic displays and other power requirements, more particularly, a power supply platform comprising two conductive layers, one positive and one negative, and a non-conductive insulating layer sandwiched between the two conductive layers. Special electronic components such as light emitting diodes (LEDs), motors, motor-driven gears, stationary gears, LED letters, air blowing devices, liquid moving devices, pre-printed artwork, sound modules, model train tracks, model train accessories, and so forth. may be removably attached to, displayed, and powered by the power supply platform simply by inserting the electronic component's positive and negative leads into the surface of the power supply platform.

Currently, LED display and lighting panels use fixedly mounted LEDs and/or other electronic components in fixed circuits which require resistors and fixed positive and negative anode polarity of the LEDs. LEDs and other electrical components with no in line resistance can burn out due to high current (i.e., amperage) and thus have a shorter life span than LEDs and electronic components with in line resistance. Also, LEDs will not work unless such are properly inserted to account for positive and negative polarity of the LEDs. Due to the latter, LEDs and other electronic components must be fixedly attached to circuit boards which have resistors in the circuit. Accordingly, electronic displays made from LEDs are permanent and cannot be changed.

Thus, a need exists for a power supply platform which provides in line resistance and proper polarity for LEDs and other electronic components without the use of fixed circuits having resistors thereby allowing the user to create any design he/she desires with removably attachable LEDs and other electronic components without regard to polarity or X-Y orientation.

### SUMMARY OF THE INVENTION

Objects of patentable novelty and utility taught by this invention are to provide a power platform which:

may be used in numerous electronic power applications;

is capable of displaying a variety of LEDs and/or other electronic components;

is capable of powering a variety of LEDs and/or other electronic components;

provides in line resistance for LEDs and other electronic components; and

provides removably attachable LEDs and other electronic components.

The present invention fulfills the above and other objects by providing a power supply platform made up of an upper conductive layer, a lower conductive layer and a non-conductive insulating layer sandwiched between the conductive layers. Specially designed light emitting diodes (LEDs) and a variety of other electronic components such as motors, motor driven gears, stationary gears, LED letters, air blowing devices, liquid moving devices, pre-printed artwork, sound modules, model train tracks, model train accessories, etc. may be removably attached to, displayed, and powered by the power supply platform simply by inserting the LEDs and/or other electronic component's positive and negative leads into the display surface of the power supply platform. The leads of the LEDs and other electronic components are different lengths so that when inserted into the display surface a shorter lead only comes into contact with the upper conductive layer and a longer lead only comes into contact with the lower conductive layer. The leads of the LEDs and/or other electronic components may be inserted into the display surface at any location allowing the user to make any design he/she desires and also allowing the user the capability of easily changing the design at any time. An optional wire mesh may be embedded into the conductive layers or a metal plate may be placed under the lower conductive layer for more even distribution of electrical power, particularly in applications requiring more power such as displays with a great number of LEDs and/or other electronic components.

The above and other objects, features and advantages of the present invention should become even more readily apparent to those skilled in the art upon a reading of the following detailed description in conjunction with the drawings wherein there is shown and described illustrative embodiments of the invention.

### BRIEF DESCRIPTION OF THE DRAWINGS

In the following detailed description, reference will be made to the attached drawings in which:

FIG. 1 is a front view of the power supply platform and electronic component of the present invention;

FIG. 2 is a side cross-section view of the power supply platform and electronic component of the present invention;

FIG. 3 is a top view of an optional wire mesh in the conductive layers of the present invention;

FIG. 4 is a side cross-section view of the power supply platform of the present invention mounted on a metal plate;

FIG. 5 is a side view of an LED with a non-conductive coating;

FIG. 6 is a top view of an insulating sleeve;

FIG. 7 is a side view of an insulating sleeve in use with an LED; and

FIG. 8 is a side cross section view of an insulating sleeve in use with an LED and the power supply platform of the present invention;

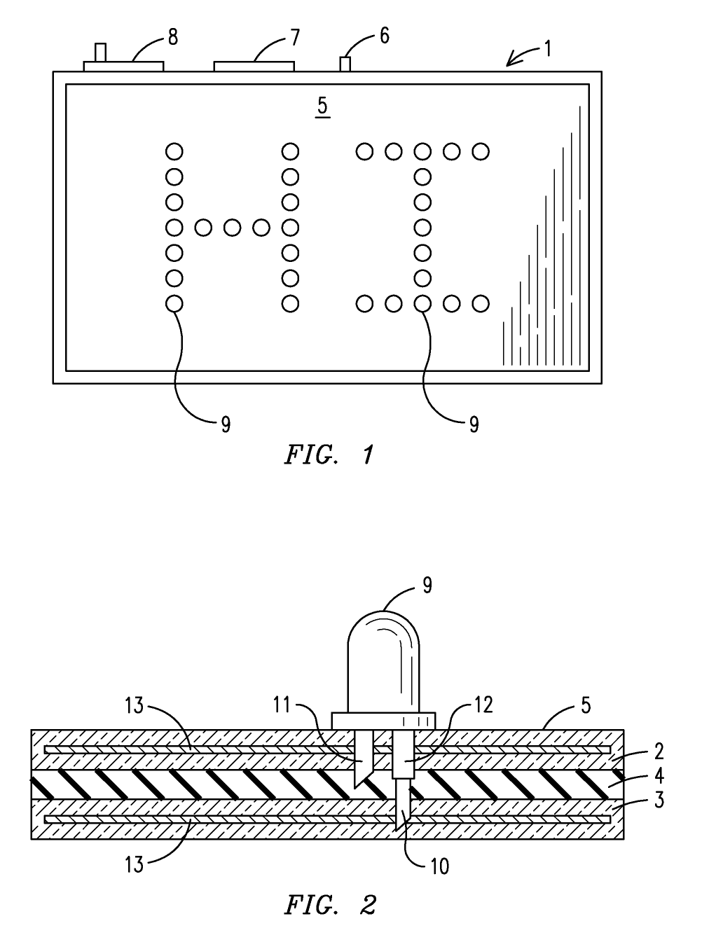

### DESCRIPTION OF THE PREFERRED EMBODIMENTS

For purposes of describing the preferred embodiment, the terminology used in reference to the numbered components in the drawings is as follows:

1. power supply platform

2. upper conductive layer

3. lower conductive layer

4. insulating layer

5. display surface

6. on/off switch

7. power jack

8. dimmer switch

9. LED

10. long lead

11. short lead

12. non-conductive coating

13. wire mesh

14. conductive plate

15. insulating sleeve

16. base

17. lead hole

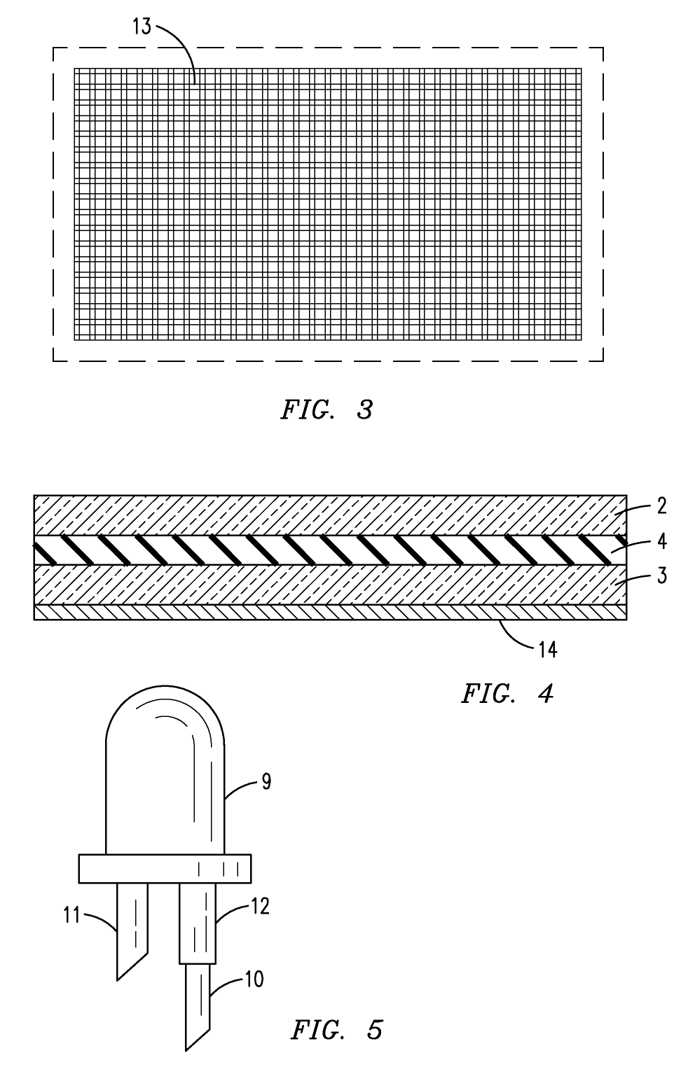

The power supply platform 1 of the present invention features an upper conductive layer 2, a lower conductive layer 3, and an insulating layer 4 sandwiched between the two conductive layers 2, 3. The upper conductive layer 2 and lower conductive layer 3 are preferably constructed out of a mixture of non-conductive material such as rubber, silicone, etc. mixed with a conductive material, such as copper, silver, nickel, graphite, carbon, etc. To ensure a proper and even supply of power throughout the power supply platform 1, particularly in applications requiring more electrical power, a wire mesh 13 made of a conductive material may be encased in the upper conductive layer 2 and/or the lower conductive layer 3 as shown in FIG. 2 and FIG. 3. In the alternative or in addition to the wire mesh 13, a conductive plate 14 made of a conductive material may be sandwiched between the upper conductive layer 2 and the insulating layer 4 and/or attached to the bottom of the lower conductive layer 3 as shown in FIG. 4. The conductive plate 14 would serve the same purpose as the wire mesh 13 which is to provide an even supply of power across the power supply platform. The upper conductive layer 2 and lower conductive layer 3 are separated by the insulating layer 4 which is preferably constructed out of a non-conductive material such as rubber.

The upper conductive layer 2 and lower conductive layer 3 may be powered with an electrical A/C or D/C power source, which plugs into a power jack 7 located on the power platform 1, or with batteries. Power may be turned on or off through the use of an on/off switch 6 located on the power supply platform 1. In addition, the level of power being supplied to the power supply platform 1 may be controlled through the use of a dimmer switch 8 located on the power supply platform 1

The display surface 5 is capable of receiving light emitting diodes (LEDs) 9 and/or other electronic component components such as motors, motor driven gears, stationary gears, LED letters, air blowing devices, liquid moving devices, pre-printed artwork, sound modules, model train tracks, model train accessories, etc. LEDs 9 and/or other electronic component components are attached to the power platform 1 at the display surface 5. Leads 10, 11 are inserted into the display surface 5 and, depending on the length of the leads 10, 11 pass through the upper conductive layer 2, the insulating layer 4, and the lower conductive layer 3. The LEDs 9 and other electronic components have at least one long lead 10 and at least one short lead 11 to ensure proper polarity. When the LEDs 9 and other electronic components are inserted into the power supply platform 1 the short lead 12 passes through the display surface 5, the upper conductive layer 2, and ends at or in the insulating layer 4. The short lead 11 never comes into contact with the lower conductive layer 3. When the components are inserted into the power supply platform 1 the long lead passes through the display surface 5, the upper conductive layer 2, the insulating layer 4, and ends in the lower conductive layer 3. The LEDs 9 and/or other electronic components may be removably attached by inserting the leads 10, 11 into the electrical display at any location on the display surface 5 allowing the user to created any design he/she desires. The mixture of the non-conductive and conductive materials in the upper conductive layer 2 and lower conductive layer 3 provide resistance to the LEDs 9 and/or other electronic components while the wire mesh 13 ensures a proper power supply at all locations on the display surface 5.

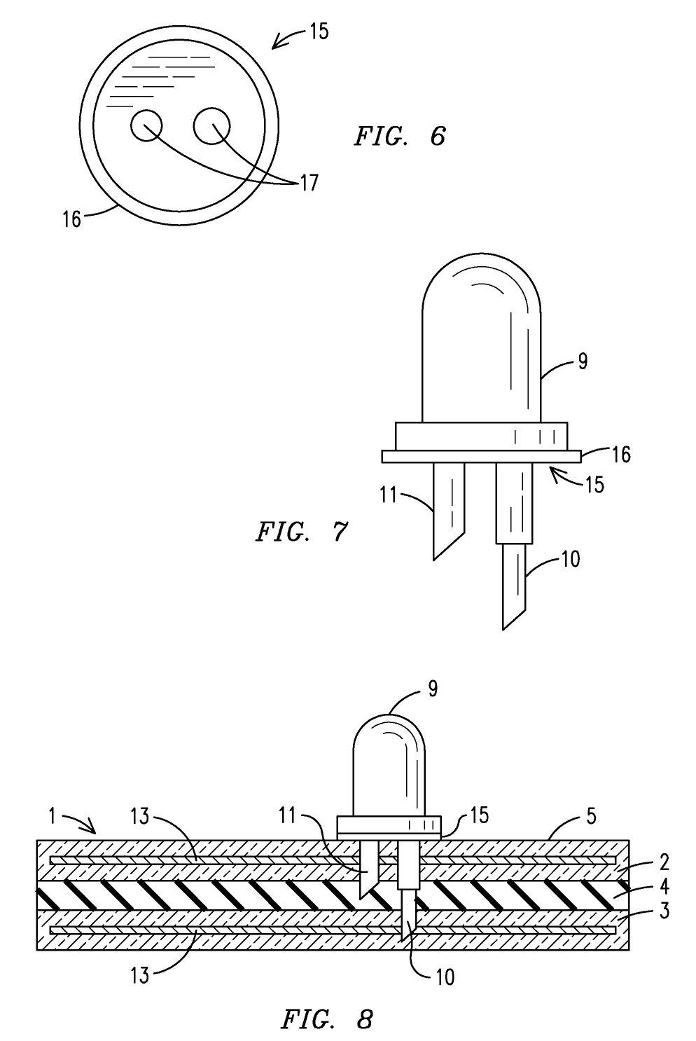

Because the long lead 10 makes contact with the upper conductive layer 2 when the long lead 10 passes through through the upper conductive layer 2, a non-conductive material is applied to the upper portion of the long lead 10 creating a non-conductive coating 12. The non-conductive coating 12 prevents contact between the upper conductive layer 2 and the long lead 10. In the alternative, an insulating sleeve 15 may be used instead of the non-conductive coating 12 to retrofit pre-existing LEDs 9 and/or other electronic components for use with the power platform 1. The insulating sleeve 15 is constructed out of a non-conductive material such as plastic, rubber, etc. and having a base 16 and lead holes 17 for the short lead 11 and the long lead 10 to pass through acts as a cap which fits over LEDs 9 and/or other electronic components to insulate the upper portion of the long lead 10 as shown in FIG. 8.

It is to be understood that while a preferred embodiment of the invention is illustrated, it is not to be limited to the specific form or arrangement of parts herein described and shown. It will be apparent to those skilled in the art that various changes may be made without departing from the scope of the invention and the invention is not be considered limited to what is shown and described in the specification and drawings.

Having thus described my invention, I claim:

1. A power supply platform comprising:
an upper conductive layer;
a lower conductive layer;
a non-conductive insulating layer between said upper conductive and lower conductive layers; and
a power source in communication with said upper conductive and lower conductive layers.

2. The power supply platform of claim 1 wherein:
said upper conductive layer comprises at least one non-conductive material and at least one conductive material; and
said lower conductive layer comprises at least one non-conductive material and at least one conductive material.

3. The power supply platform of claim 1 wherein:
said upper conductive layer comprises at least one non-conductive material and at least one conductive material;
said lower conductive layer comprises at least one non-conductive material and at least one conductive material;
said upper conductive layer further comprises a wire mesh; and said wire mesh is a conductive material.

4. The power supply platform of claim 1 wherein:
said upper conductive layer comprises at least one non-conductive material and at least one conductive material;
said lower conductive layer comprises at least one non-conductive material and at least one conductive material;
said lower conductive layer further comprises a wire mesh; and
said wire mesh is a conductive material.

5. The power supply platform of claim 1 wherein:
said upper conductive layer comprises at least one non-conductive material and at least one conductive material;
said lower conductive layer comprises at least one non-conductive material and at least one conductive material;
said upper conductive layer further comprises a wire mesh;
said lower conductive layer further comprises a wire mesh; and
said wire mesh is a conductive material.

6. The power supply platform of claim 1 further comprising:
a conductive plate.

7. The power supply platform of claim 1 wherein:
said power source is an A/C power source.

8. The power supply platform of claim 1 wherein:
said power source is a D/C power source.

9. The power supply platform of claim 1 wherein:
said power source is at least one battery.

10. The power supply platform of claim 1 wherein:
an on/off switch controls the power source.

11. The power supply platform of claim 1 wherein:
a dimmer switch controls the power level.

12. An electronic component comprising:
a short lead;
a long lead; and
a means for insulating the upper portion of said long lead.

13. The electronic component of claim 12 wherein:
said short lead is negative; and
said long lead is positive.

14. The electronic component of claim 12 wherein:
said short lead is positive; and
said long lead is negative.

15. The electronic component of claim 12 wherein:
said means for insulating the upper portion of said long negative lead comprises a coating of non-conductive material.

16. The electronic component of claim 12 wherein:
said means for insulating the upper portion of said long negative lead comprises an insulating sleeve;
said insulating sleeve being attached to bottom of said electrical component; and
said insulating sleeve comprises a non-conductive material.

17. The electronic component of claim 12 wherein:
said electrical component is a light emitting diode.

18. The electronic component of claim 12 wherein:
said electrical component is a light emitting diode; and
said means for insulating the upper portion of said long negative lead comprises a coating of non-conductive material.

19. The electronic component of claim 12 wherein:
the electrical component is a light emitting diode;
said means for insulating the upper portion of said long negative lead comprises an insulating sleeve;
said insulating sleeve is attached to bottom of said electrical component; and
said insulating sleeve comprises a non-conductive material.

20. A power supply platform and electronic component comprising:
an upper conductive layer;
a lower conductive layer;
a non-conductive insulating layer between said upper conductive layer and lower conductive layer;
a power source in communication with said upper conductive layer and lower conductive layer;
at least one electronic component having a short lead and a long lead;
said electronic component is powered by said upper conductive layer and lower conductive layer; and
a means for insulating the upper portion of said long lead.

21. The power supply platform and electronic component of claim 20 wherein:
said short lead is negative; and
said long lead is positive.

22. The power supply platform and electronic component of claim 20 wherein:
said short lead is positive; and
said long lead is negative.

23. The power supply platform and electronic component of claim 20 wherein:
said upper conductive layer comprises at least one non-conductive material and at least one conductive material; and
said lower conductive layer comprises at least one non-conductive material and at least one conductive material.

24. The power supply platform and electronic component of claim 20 wherein:
said upper conductive layer further comprises a wire mesh;
said wire mesh is a conductive material.

25. The power supply platform and electronic component of claim 20 wherein:
said lower conductive layer further comprises a wire mesh; and
said wire mesh is a conductive material.

26. The power supply platform and electronic component of claim 20 wherein:
said upper conductive layer further comprises a wire mesh;
said lower conductive layer further comprises a wire mesh;
said wire mesh is a conductive material;

27. The power supply platform and electronic component of claim 20 further comprising:
a conductive plate attached to the lower conductive layer.
